(19) United States
(12) Patent Application Publication
(10) Pub. No.: US 2025/0251473 A1
(43) Pub. Date: Aug. 7, 2025

(54) SUPERCONDUCTING MAGNET AND MAGNETIC RESONANCE IMAGING APPARATUS

(71) Applicant: Canon Medical Systems Corporation, Otawara-shi (JP)

(72) Inventors: Katsutoshi MIZUNO, Nasushiobara (JP); Takehiro SHIBUYA, Nasushiobara (JP)

(73) Assignee: Canon Medical Systems Corporation, Otawara-shi (JP)

(21) Appl. No.: 19/003,026

(22) Filed: Dec. 27, 2024

(30) Foreign Application Priority Data
Feb. 2, 2024 (JP) 2024-015137

(51) Int. Cl. G01R 33/34; H01F 6/04; H01F 6/06

(52) U.S. Cl. CPC G01R 33/34023; G01R 33/3403; H01F 6/04; H01F 6/06

(57) ABSTRACT

According to an embodiment, a superconducting magnet includes a loop-shaped superconducting coil and a cryostat. The loop-shaped superconducting coil forms a static magnetic field. The cryostat has a top plate portion and a bottom plate portion and is a housing storing the superconducting coil. In at least one of a space on an inner peripheral side or a space on an outer peripheral side of the superconducting coil, a part of at least one of the top plate portion or the bottom plate portion is bent toward an inner side of the cryostat and joined to a part of the other of the top plate portion or the bottom plate portion.

### CROSS-REFERENCE TO RELATED APPLICATIONS

This application is based upon and claims the benefit of priority from Japanese Patent Application No. 2024-015137, filed Feb. 2, 2024, the entire contents of which are incorporated herein by reference.

### FIELD

Embodiments described herein relate generally to a superconducting magnet and a magnetic resonance imaging apparatus.

### BACKGROUND

Imaging performed by a general cylindrical magnetic resonance imaging apparatus forces a subject not to move for a long time inside a narrow bore and also puts the subject under the noise attributed to switching of gradient magnetic fields and the like, causing stress to the subject. Thus, in order to alleviate the psychological anxiety caused by the closed space, an open magnetic resonance imaging apparatus, in which a pair of static magnetic field magnets vertically face each other and the side from which the subject is inserted is opened, has come into wide use.

Since the open magnetic resonance imaging apparatus has static magnetic field magnets that are vertically independent, the gantry part tends to become large. There is thus a need to reduce the size and weight of the gantry part to the extent possible. On the other hand, in view of broadening the imaging space, it is possible to increase the size of the gantry part, which, however, causes a problem in that the components of the housing may warp as the housing becomes larger.

### BRIEF DESCRIPTION OF THE DRAWINGS

FIG. 1 is a conceptual diagram of a gantry part of a magnetic resonance imaging apparatus according to an embodiment.

FIG. 2 is a block diagram showing the magnetic resonance imaging apparatus according to the embodiment.

FIG. 3 is a cross-sectional diagram according to a first example of a configuration of a superconducting magnet.

FIG. 4 is a diagram showing a positional relationship between a superconducting coil and a shim according to the first example of the configuration of the superconducting magnet.

FIG. 5 is a cross-sectional diagram according to a second example of a configuration of a superconducting magnet.

FIG. 6 is a diagram showing a positional relationship between a superconducting coil and a shim according to the second example of the configuration of the superconducting magnet.

FIG. 7 is a cross-sectional diagram according to a third example of a configuration of a superconducting magnet.

FIG. 8 is a cross-sectional diagram according to a fourth example of a configuration of a superconducting magnet.

FIG. 9 is a diagram showing a positional relationship among a superconducting coil, a shim, a cold head, and a refrigerator according to the fourth example of the configuration of the superconducting magnet.

### DETAILED DESCRIPTION

In general, according to an embodiment, a superconducting magnet according to an embodiment includes a superconducting coil and a cryostat. The superconducting coil forms a static magnetic field and has a loop shape. The cryostat has a top plate portion and a bottom plate portion and is a housing for storing the superconducting coil. In at least one of a space on the inner peripheral side or a space on the outer peripheral side of the superconducting coil, a part of at least one of the top plate portion or the bottom plate portion is bent toward the inner side of the cryostat and joined to a part of the other of the top plate portion or the bottom plate portion.

A superconducting magnet and a magnetic resonance imaging apparatus according to an embodiment will be described with reference to the accompanying drawings. In the embodiments described below, elements assigned the same reference symbols are assumed to perform the same operations, and redundant descriptions thereof will be omitted as appropriate. Hereinafter, an embodiment will be described with reference to the accompanying drawings.

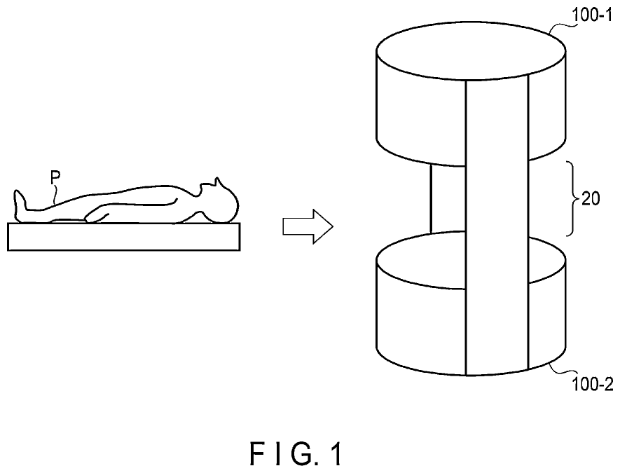

Next, a conceptual diagram of a gantry part of the magnetic resonance imaging apparatus according to the embodiment will be described with reference to FIG. 1.

The magnetic resonance imaging apparatus according to the embodiment is assumed to be an open magnetic resonance imaging apparatus. That is, the gantry part of the magnetic resonance imaging apparatus is configured so that an upper gantry part 100-1 and a lower gantry part 100-2 are arranged to face each other. A uniform static magnetic field is generated in the space where the upper gantry part 100-1 and the lower gantry part 100-2 face each other, and this space becomes an imaging space 20. A subject P is inserted into the imaging space 20, and imaging is performed by generating a gradient magnetic field and radiating an RF pulse according to an imaging sequence.

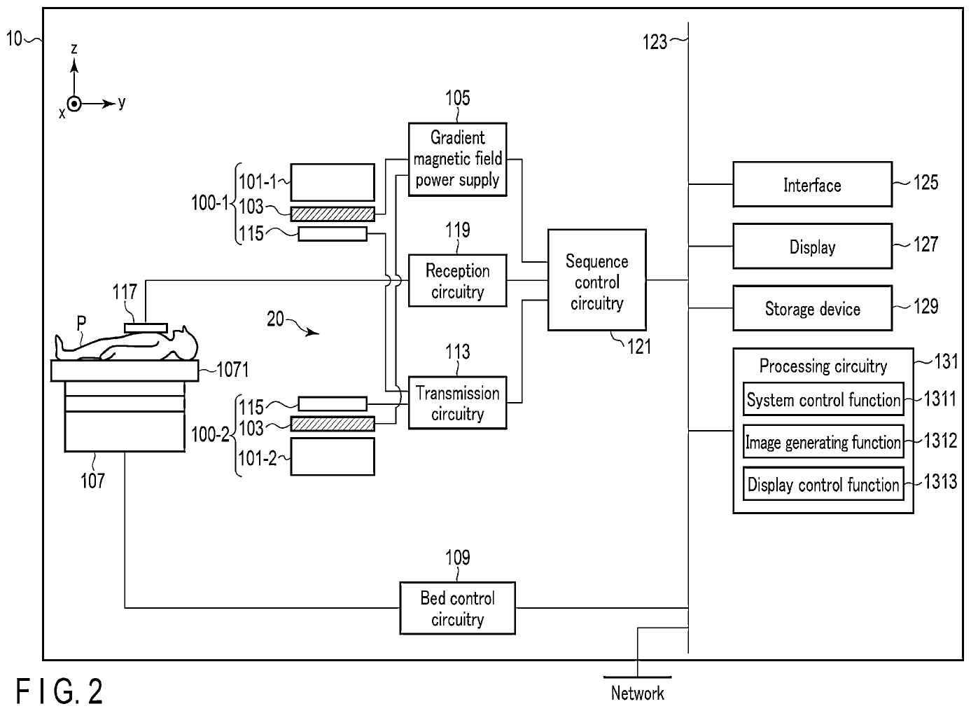

Next, the magnetic resonance imaging apparatus according to the embodiment will be described with reference to the block diagram of FIG. 2.

A magnetic resonance imaging apparatus 10 includes a static magnetic field magnet, a gradient magnetic field coil 103, a gradient magnetic field power supply 105, a bed 107, bed control circuitry 109, transmission circuitry 113, a transmitter coil 115, a receiver coil 117, reception circuitry 119, sequence control circuitry 121, a bus 123, an interface 125, a display 127, a storage device 129, and processing circuitry 131.

The static magnetic field magnet is assumed to be a pair of superconducting magnets (the upper superconducting magnet 101-1 and the lower superconducting magnet 101-2) that uses a superconducting coil. The static magnetic field magnet generates a uniform static magnetic field in the space where the static magnetic field magnets face each other.

The gradient magnetic field coil 103 is arranged on the inner side of the static magnetic field magnet. The gradient magnetic field coil 103 is formed of a combination of three coils respectively corresponding to x-, y-, and z-axes that are orthogonal to each other. The z-axis direction is the same as the direction of the static magnetic field. The y-axis direction is a horizontal direction, and the x-axis direction is a direction perpendicular to the z-axis and the y-axis. The three coils of the gradient magnetic field coil 103 are individually supplied with an electric current from the gradient magnetic field power supply 105, and generate gradient magnetic fields whose magnetic field intensity changes along the respective x-, y-, and z-axes.

The gradient magnetic field of each of the x-, y-, and z-axes generated by the gradient magnetic field coil 103 forms, for example, a gradient magnetic field for frequency encoding (also referred to as a “readout gradient magnetic field”), a gradient magnetic field for slice selection, and a gradient magnetic field for phase encoding. The gradient magnetic field for frequency encoding is used to change a frequency of an MR signal accordance to a spatial position. The gradient magnetic field for slice selection is used to determine an imaging cross-section. The gradient magnetic field for phase encoding is used to change a phase of an MR signal accordance to a spatial position.

The gradient magnetic field power supply 105 is a power supply apparatus that supplies an electric current to the gradient magnetic field coil 103 under the control of the sequence control circuitry 121.

The bed 107 is an apparatus with a bed top 1071 on which a subject P is placed. The bed 107 moves the bed top 1071 on which the subject P is placed toward the imaging space 20 under the control of the bed control circuitry 109. For example, the bed 107 is installed in an examination room, where the magnetic resonance imaging apparatus 10 is installed, such that a longitudinal direction of the bed 107 is perpendicular to the central axis of the static magnetic field magnet.

The bed control circuitry 109 is circuitry that controls the bed 107, and drives the bed 107 in response to a user's instruction via the interface 125 to move the bed top 1071 in the longitudinal direction and the vertical direction.

The transmitter coil 115 is an RF coil arranged on an inner side of the gradient magnetic field coil 103. The transmitter coil 115 is supplied with a radio frequency (RF) pulse from the transmission circuitry 113, and generates a transmit RF wave corresponding to a high-frequency magnetic field. The transmitter coil 115 is, for example, a whole-body coil. The whole-body coil may be used as a transmitter/receiver coil. A cylindrical RF shield is installed between the whole-body coil and the gradient magnetic field coil 103 to magnetically separate these coils.

The transmission circuitry 113 supplies an RF pulse corresponding to a Larmor frequency, etc., to the transmitter coil 115 under the control of the sequence control circuitry 121.

The receiver coil 117 is an RF coil arranged on an inner side of the gradient magnetic field coil 103. The receiver coil 117 receives an MR signal emitted from the subject P through a high-frequency magnetic field. The receiver coil 117 outputs the received MR signal to the reception circuitry 119. The receiver coil 117 is, for example, a coil array including one or more, typically, a plurality of coil elements. The receiver coil 117 is, for example, a phased array coil.

Under the control of the sequence control circuitry 121, the reception circuitry 119 generates a digital MR signal, which is digitized complex data, based on the MR signal output from the receiver coil 117. Specifically, the reception circuitry 119 performs various types of signal processing on the MR signal output from the receiver coil 117, and then performs analog-to-digital (A/D) conversion on the data subjected to the various types of signal processing. The reception circuitry 119 samples the A/D-converted data. The reception circuitry 119 thereby generates a digital MR signal (hereinafter referred to as “MR data”). The reception circuitry 119 outputs the generated MR data to the sequence control circuitry 121.

The sequence control circuitry 121 controls the gradient magnetic field power supply 105, the transmission circuitry 113, and the reception circuitry 119, etc., according to an examination protocol output from the processing circuitry 131, and performs imaging of the subject P. The examination protocol includes various pulse sequences, that is, imaging sequences, corresponding to the examination.

The bus 123 is a transmission path for transmitting data among the interface 125, the display 127, the storage device 129, and the processing circuitry 131. The bus 123 may be connected, via a network, etc., to various biosignal measuring instruments, an external storage device, various modalities and the like, as appropriate. For example, an electrocardiograph (not shown) is connected to the bus as a biosignal measuring instrument.

The interface 125 includes an input device that receives various commands from a user. Examples of the input device that can be used include a keyboard, a mouse, various switches, a touch screen, and a touch pad. The input device is not limited to those provided with physical operational components such as a mouse and a keyboard. Examples of the interface 125 also include electric signal processing circuitry that receives an electric signal corresponding to an input operation from an external input device provided separately from the magnetic resonance imaging apparatus 10, and outputs the received electric signal to various types of circuitry. The interface 125 may also be a voice recognition device that collects voice signals via a microphone and converts the voice signals into command signals.

Under the control of a system control function 1311 of the processing circuitry 131, the display 127 displays, for example, various magnetic resonance images (MR images), such as a T1 enhanced image and a T2 enhanced image, generated by an image generation function 1312, and various kinds of information relating to imaging and image processing. The display 127 is, for example, a display device such as a CRT display, a liquid crystal display, an organic EL display, an LED display, a plasma display, or any other display or monitor known in this technical field.

The storage device 129 stores MR data with which a k space is filled through the image generation function 1312, image data generated by the image generation function 1312, etc. The storage device 129 stores various examination protocols, imaging conditions including multiple imaging parameters that define the examination protocols, etc. The storage device 129 stores programs corresponding to various functions implemented by the processing circuitry 131. The storage device 129 is, for example, a ROM (read-only memory), a RAM (random access memory), a semiconductor memory device such as a flash memory, a hard disk drive, a solid-state drive, an optical disk, or the like. The storage device 129 may be, for example, a driver that reads and writes various kinds of information from and to a portable storage medium such as a CD-ROM drive, a DVD drive, or a flash memory.

The processing circuitry 131 includes, as hardware resources, a processor (not shown), a memory such as a ROM and a RAM, etc., and collectively controls the magnetic resonance imaging apparatus 10. The processing circuitry 131 includes the system control function 1311, the image generation function 1312, and a display control function 1313.

With the system control function 1311, the processing circuitry 131 performs control to apply an excitation pulse according to an excitation pulse sequence and apply a gradient magnetic field. After executing the excitation pulse sequence by implementing the system control function 1311, the processing circuitry 131 collects MR signals from the subject P according to a data collection sequence, which is a pulse sequence for collecting various types of data, and generates MR data.

With the image generation function 1312, the processing circuitry 131 fills the k space with the MR data along a readout direction of the k space according to the intensity of a readout gradient magnetic field. With the image generation function 1312, the processing circuitry 131 generates an MR image by performing a Fourier transform on the MR data with which the k space is filled. For example, the processing circuitry 131 can generate an absolute value (magnitude) image from complex MR data. The processing circuitry 131 can also generate a phase image using real-part data and imaginary-part data in the complex MR data.

With the display control function 1313, the processing circuitry 131 causes an MR image to be displayed on the display 127. With the display control function 1313, the processing circuitry 131 may perform control to transmit the MR image to a network so that the MR image is displayed on, for example, a computer in an examination room, an in-hospital workstation, or the like.

The various functions of the processing circuitry 131 are stored in the storage device 129 in the form of a program executable by a computer. The processing circuitry 131 is a processor that reads the programs corresponding to the various functions from the storage device 129 and executes the programs to thereby fulfill the functions corresponding to the respective programs. In other words, the processing circuitry 131 that has read each program has multiple functions shown in the processing circuitry 131 in FIG. 2, and the like.

FIG. 2 illustrates that the various functions are implemented by the single processing circuitry 131; however, a plurality of independent processors may be combined to constitute the processing circuitry 131, so that the functions are implemented by the respective processors executing the programs. In other words, each of the above-described functions may be configured as a program so that single processing circuitry executes each program, or a specific function may be implemented in dedicated, independent program execution circuitry.

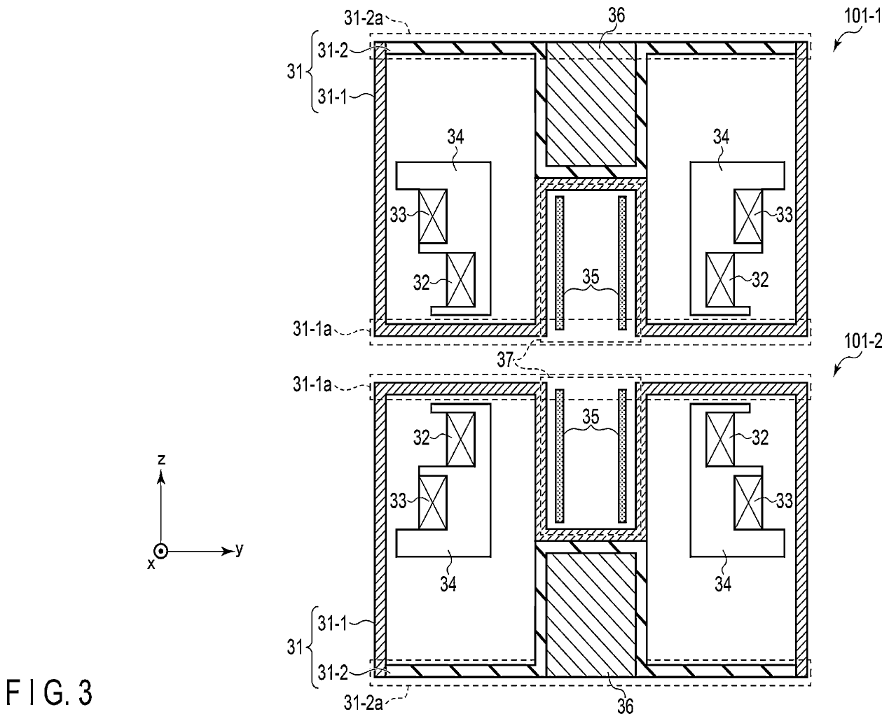

Next, a first example of a configuration of the superconducting magnet 101 according to the embodiment will be described with reference to FIG. 3.

FIG. 3 is a cross-sectional view passing through the cylindrical center of the upper superconducting magnet 101-1 and the lower superconducting magnet 101-2. Herein, the upper superconducting magnet 101-1 and the lower superconducting magnet 101-2 will be explained collectively as a superconducting magnet 101 since they have the same configuration in which they are arranged symmetrically with respect to an imaging space.

The superconducting magnet 101 includes a cryostat 31, two superconducting coils, which are a superconducting coil 32 and a superconducting coil 33, a support 34, a shim 35, a reinforcer 36, and a shim fixer 37.

The cryostat 31 has a top plate portion and a bottom plate portion and is a housing for storing the superconducting coil 32 and the superconducting coil 33. Specifically, the cryostat 31 is a vacuum container that has a first housing member 31-1 including a top plate portion 31-1a and a second housing member 31-2 including a bottom plate portion 31-2a and is formed by joining and fixing the first housing member 31-1 and the second housing member 31-2 together. In the example shown in FIG. 3, the surface of the first housing member 31-1 that faces the other superconducting magnet 101 is called a top plate portion 31-1a. The surface of the second housing member 31-2 that is opposite to the top plate portion 31-1a of the first housing member 31-1 is called a bottom plate portion 31-2a. The cryostat 31 is filled with liquid helium, so that the superconducting coil 32 and the superconducting coil 33 are immersed in the liquid helium. The cryostat 31 described below is not limited to being formed by joining the first housing member 31-1 and the second housing member 31-2 together. The cryostat 31 may be in integral construction or formed by suitably joining three or more members.

The superconducting coil 32 and the superconducting coil 33 are loop-shaped coils that generate static magnetic fields and are stored in the cryostat 31. The superconducting coil 32 and the superconducting coil 33 are arranged such that the opening of the loop faces in the vertical direction (the z-axis direction in FIG. 3). The superconducting coil 32 and the superconducting coil 33 are designed so that electric currents flow in opposite directions to each other so as to reduce magnetic field leakage. While two superconducting coils are shown as an example herein, the embodiment is not limited thereto. Three or more superconducting coils may form static magnetic fields. Hereinafter, the two superconducting coils, which are the superconducting coil 32 and the superconducting coil 33, will also be simply collectively called a superconducting coil, as necessary.

The support 34 is stored in the cryostat 31 and supports the superconducting coil 32 and the superconducting coil 33.

The shim 35 is a shimming magnet capable of adjusting the static magnetic fields generated by the superconducting coil 32 and the superconducting coil 33. The shim 35 may be formed of, for example, a shim tray, a shim coil, or the like that stores multiple plates of magnets such as iron and copper. Herein, the shim 35 is assumed to be arranged in a cylindrical shape inside the region where the shim fixer 37 is located.

The shim fixer 37, to which the shim 35 is fixed, is formed in the center of the cylinder of the cryostat 31. For example, the shim fixer 37 is formed in a space formed by a part of at least one of the top plate portion 31-1a or the bottom plate portion 31-2a of the cryostat 31 bent toward the inner side of the cryostat 31 and joined to a part of the other one in at least one of a space on the inner peripheral side or a space on the outer peripheral side of the superconducting coil, that is, the shim fixer 37 is formed in a space outside the cryostat 31. That is, in FIG. 3, the shim fixer 37 is formed in a region where the first housing member 31-1 and the second housing member 31-2 forming the cryostat 31 have a concave structure toward the inner side of the housing of the cryostat 31.

Let us take the upper superconducting magnet 101-1, for example. The second housing member 31-2 is bent (concaved) toward the inner side of the cryostat 31, and the first housing member 31-1 is bent (convexed) toward the inner side of the cryostat 31, so that they form a flange structure with respect to each other, whereby they are joined together.

Let us take the lower superconducting magnet 101-2, for example. The first housing member 31-1 is concaved toward the inner side (the bottom plate side) of the cryostat 31, and the second housing member 31-2 is convexed toward the inner side (the top plate side) of the cryostat 31, so that they form a flange structure with respect each other, whereby they are joined together.

The position (height) in the z-axis direction at which a part of the first housing member 31-1 and a part of the second housing member 31-2 are joined together may be discretionary as long as it allows the shim 35 and the shim fixer 37 to be arranged. For example, the length of the shim fixer 37 in the z-axis direction may be set to a minimum length that allows the shim 35 to adjust the static magnetic field according to the length of the superconducting coil in the z-axis direction.

The portion where the first housing member 31-1 and the second housing member 31-2 are bent and joined to each other is not limited to be formed by a flange structure, and may be formed by bending, welding, adhesion, bolt tightening, press fitting, cooling fitting, shrink fitting, rivet fastening, etc. That is, a structure that can join the first housing member 31-1 and the second housing member 31-2 together and maintain the vacuum state inside the cryostat 31 suffices.

The reinforcer 36 is arranged in the upper or lower side of the shim fixer 37 that is arranged outside the cryostat 31 and formed of a material having a strength such as stainless steel or a resin. Only the reinforcer 36 may be arranged without the shim 35 being inserted into the shim fixer 37. In the case of the upper superconducting magnet 101-1, the reinforcer 36 need not be arranged. Although FIG. 3 shows an example in which the reinforcer 36 is arranged in the entire space outside the cryostat 31 created by the second housing member 31-2 being bent, the reinforcer 36 may be arranged in part of the space as long as a desired reinforcing strength can be secured.

The thickness of the first housing member 31-1 and the second housing member 31-2 may be designed based on the size of the cryostat 31 and the expected load on the cryostat 31.

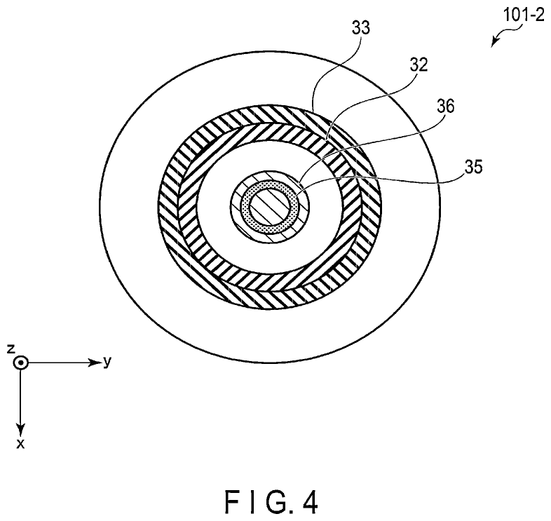

Next, a positional relationship between the superconducting coil and the shim 35 according to the first example of the configuration of the superconducting magnet 101 will be explained with reference to FIG. 4.

Specifically, FIG. 4 shows a positional relationship between the superconducting coil and the shim 35 and the reinforcer 36 of, herein, the lower superconducting magnet 101-2, seen when the superconducting magnet 101 side is observed from the imaging space 20. As shown in FIG. 4, the superconducting coil is arranged in a loop shape such that its opening faces in the z-axis direction. The shim 35 is arranged in a loop shape on the inner peripheral side of the superconducting coil (herein, the inner peripheral side of the superconducting coil 32).

In the example shown in FIG. 4, the shim 35 is continuously arranged in a loop shape; however, the shim 35 may be arranged discretely along the circumference. For example, in this case, multiple shim trays that allow pieces of iron to be arranged thereon may be prepared for the shim fixer 37 so that the shim trays are inserted into the z-axis direction discretely in multiple locations along the circumference.

Also, the reinforcer 36 is arranged in the lower side of the shim fixer 37 in the center of the superconducting magnet 101. Thus, the strength of the housing of the cryostat 31 can be increased. Further, the lower superconducting magnet 101-2 can support, for example, the load imposed when the gradient magnetic field coil 103, the transmitter coil 115, etc., are arranged on the top plate portion 31-1a.

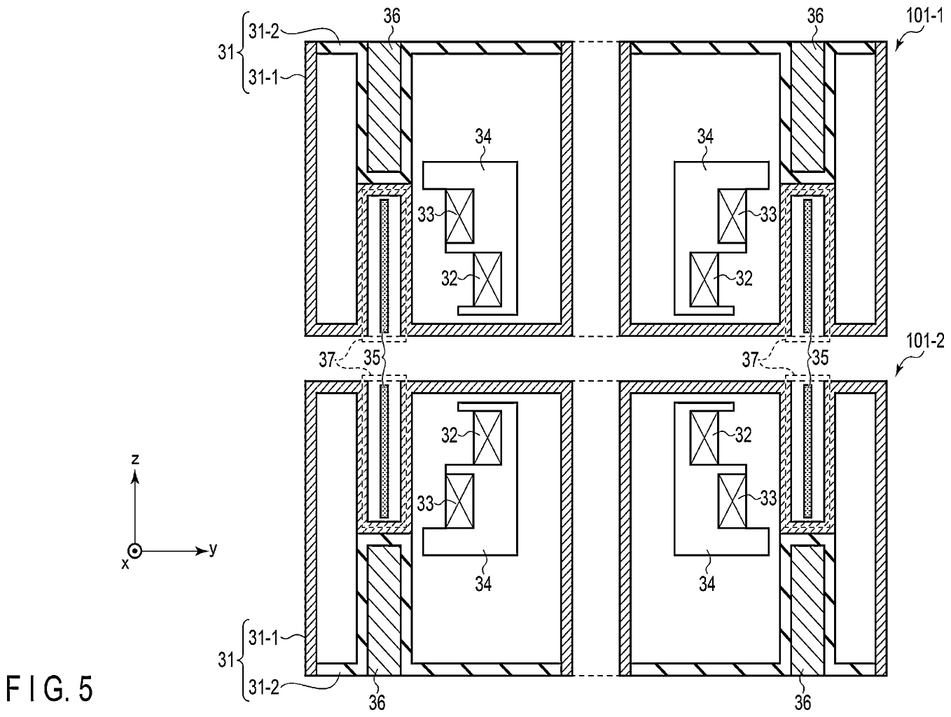

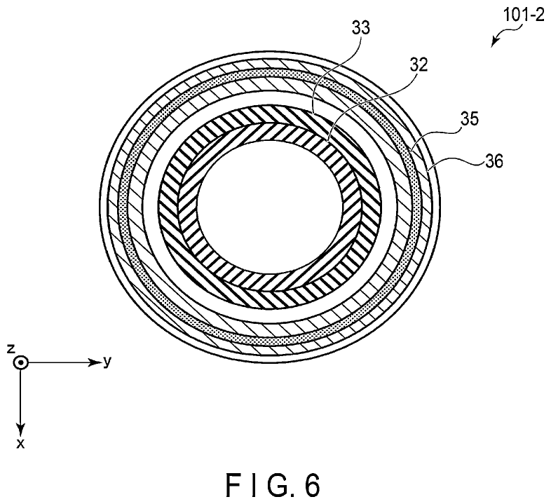

Next, a second example of a configuration of the superconducting magnet 101 according to the embodiment will be described with reference to FIG. 5 and FIG. 6.

FIG. 5 is a cross-sectional view of the upper superconducting magnet 101-1 and the lower superconducting magnet 101-2 according to the second example of the configuration of the superconducting magnet 101. FIG. 6 is a diagram showing a positional relationship between the superconducting coil and the shim 35, seen when the superconducting magnet 101 side is observed from the imaging space 20, according to the second example of the configuration of the superconducting magnet 101.

FIGS. 5 and 6 show an example in which the shim fixer 37 is not arranged on the inner side of the loop of the superconducting coil of the superconducting magnet 101 but formed outside the loop of the superconducting coil of the superconducting magnet 101 and the shim 35 is arranged there. In the case of the second example of the configuration as well, the reinforcer 36 is arranged in the space outside the cryostat 31 opposite to the shim fixer 37, as in the case of the first example of the configuration.

In this manner, the shim fixer 37 may be formed in any position from the center of the z-axis of the superconducting magnet 101 toward the radial direction. In other words, the shim fixer 37 may be formed in any position inside and outside the loop of the superconducting coil. Also, not only one shim fixer 37 but also two or more shim fixers 37 may be formed and the shim 35 may be arranged there. That is, multiple shim fixers 37 may be formed as long as a desired static magnetic field distribution is obtained.

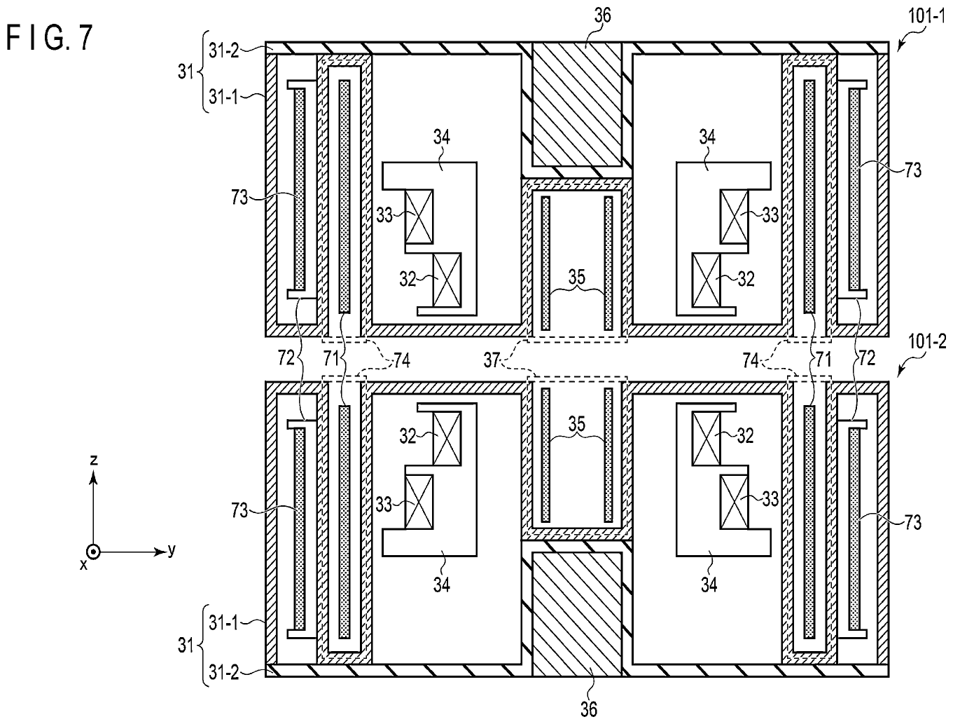

Next, a third example of a configuration of the superconducting magnet according to the embodiment will be described with reference to FIG. 7.

FIG. 7 is a cross-sectional view of the upper superconducting magnet 101-1 and the lower superconducting magnet 101-2. The superconducting magnet 101 shown in FIG. 7 includes a shim 71, a high-temperature superconducting (HTS) coil 72, an HTS coil support 73, and a shim fixer 74 in addition to the configurations shown in FIGS. 3 and 5.

The shim 71 is a shimming magnet capable of adjusting the same static magnetic field as that of the shim 35.

The HTS coil 72 is a coil having an operating temperature zone different from those of the superconducting coil 32 and the superconducting coil 33. The HTS coil 72 may be used as a countermeasure against pre-polarization, used to increase the magnetic field intensity of the static magnetic field, or used to change or adjust the static magnetic field distribution.

The HTS coil support 73 supports the HTS coil 72 inside the cryostat 31.

Specifically, in FIG. 7, the superconducting magnet 101 has the shim 71 arranged outside the loop of the superconducting coil shown in FIG. 5 (i.e., the outer peripheral side of the cryostat 31) in addition to the shim 35 on the inner peripheral side of the loop of the superconducting coil shown in FIG. 3 (i.e., the center of the cryostat 31). Further, the HTS coil 72 is stored on the outer peripheral side of the shim 71. The HTS coil 72 is stored independently from the superconducting coil 32 and the superconducting coil 33 in a region inside the cryostat 31 separated by the formation of a later-described shim fixer 74. That is, the superconducting coils are stored independently inside the cryostat 31 for each operating temperature zone.

Also, in the third example of the configuration, the shim fixer 74 that stores the shim 71 is in a region formed in a space outside the cryostat 31 by bending only the first housing member 31-1 side toward the inner side of the cryostat 31 to join it to the second housing member 31-2. That is, the second housing member 31-2 is not bent toward the inner side of the cryostat 31, unlike what is shown in FIGS. 3 and 5. Needless to say, in the third example of the configuration as well, the shim fixer 74 may be in a space outside the cryostat 31 formed by bending both the first housing member 31-1 and the second housing member 31-2 inward and joining them, as shown in FIGS. 3 and 5.

Forming the cryostat 31 in which the superconducting coils having different operating temperature zones are spatially separated from each other in this manner creates structural separation and provides housing wall faces of the cryostat 31. Thus, even if an instant variable magnetic field is set, the influence on other superconducting coils 32 and superconducting coils 33 is alleviated. The bending structure formed by the first housing member 31-1 and the second housing member 31-2, and the reinforcer 36 can increase the strength of the cryostat 31.

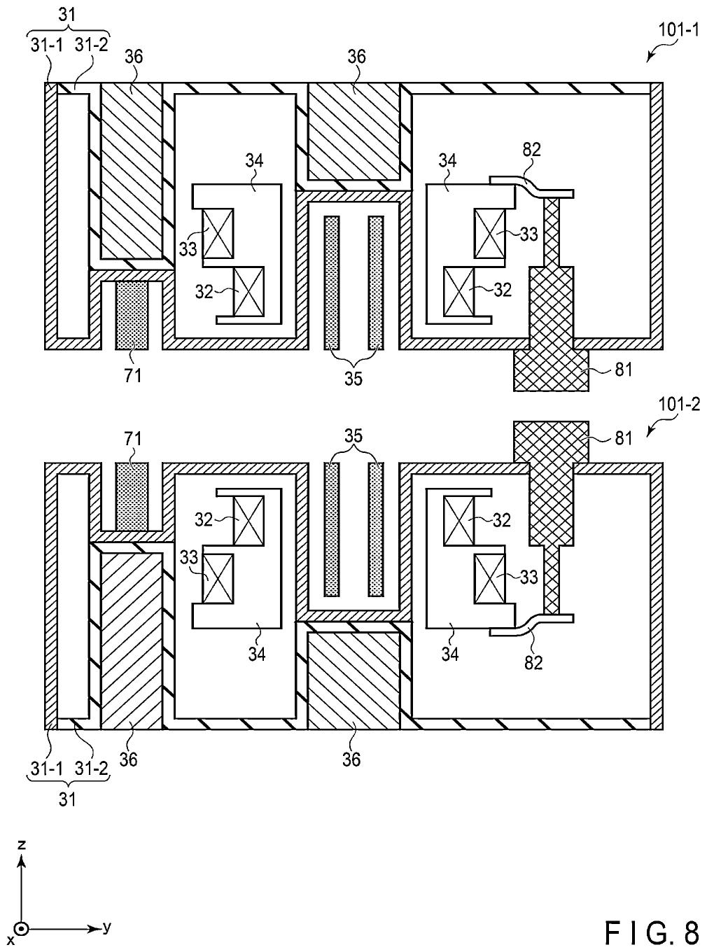

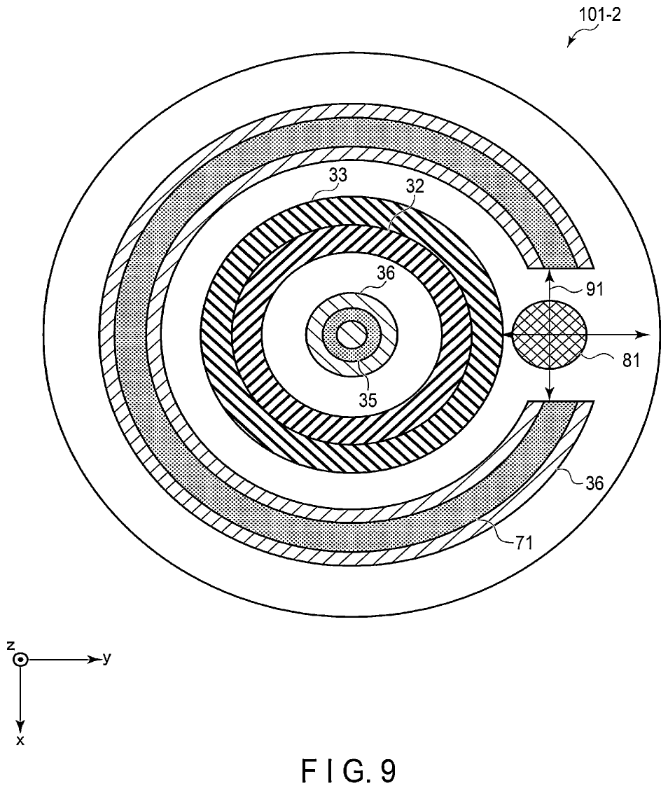

Next, a fourth example of a configuration of the superconducting magnet 101 according to the embodiment will be described with reference to FIGS. 8 and 9.

FIG. 8 is a cross-sectional view of the upper superconducting magnet 101-1 and the lower superconducting magnet 101-2 according to the fourth example of the configuration of the superconducting magnet 101.

The superconducting magnet 101 according to the fourth embodiment includes a refrigerator cold head 81 and a heat transmitter 82 in addition to the first example of the configuration shown in FIG. 3.

The refrigerator cold head 81 is arranged to cool the inside of the cryostat 31.

The heat transmitter 82 is a liquid helium pipe connected to a distal end of the refrigerator cold head 81 and is formed to cool the superconducting coil via the refrigerator cold head 81.

As shown in FIG. 8, the refrigerator cold head 81 is arranged so as to be inserted into the first housing member 31-1. Except the region where the refrigerator cold head 81 is arranged, the inside of the cryostat 31 is closed. On the other hand, a portion of the first housing member 31-1 other than the region where the refrigerator cold head 81 is arranged is bent toward the inner side of the cryostat 31 until it is connected to the second housing member 31-2. As in the third example of the configuration shown in FIG. 7, the shim 35 and the reinforcer 36 are arranged on the inner peripheral side of the superconducting coil outside the cryostat 31, and the shim 71 and the reinforcer 36 are arranged on the outer peripheral side of the superconducting coil outside the cryostat 31.

FIG. 9 shows a positional relationship among the shim 35, the shim 71, and the refrigerator cold head 81, seen when the superconducting magnet 101 side is observed from the imaging space 20, according to the fourth example of the configuration of the superconducting magnet 101.

As shown in FIG. 9, in the space on the outer peripheral side of the loop of the superconducting coil, a part of at least one of the top plate portion or the bottom plate portion other than the position of the refrigerator cold head 81 is bent toward the inner side of the cryostat 31 along the circumferential direction of the loop and joined to a part of the other of the top plate portion or the bottom plate portion. In other words, in the space on the outer peripheral side of the loop of the superconducting coil, there is a form having a C-shaped cut along the circumferential direction. The shim 71 and the reinforcer 36 are arranged along the C form. A width 91 of the cut part of the C-shaped cut in the circumferential direction may be a minimal width that allows the refrigerator cold head 81 and the heat transmitter 82 to be arranged. Also, the position of the refrigerator cold head 81 may be any position as long as the circumferential direction thereof is arranged within the range of the width 91 of the cut part and as long as the radial direction 81 thereof does not physically interfere with the superconducting coil.

According to the fourth example of the configuration shown in FIGS. 8 and 9, it is possible to provide a support structure using the reinforcer 36 outside the coil and to improve the strength of the housing of the superconducting magnet 101. Furthermore, the heat transmitter 82 secures a heat transfer path with the refrigerator cold head 81 for the liquid helium in which the superconducting coil is immersed, allowing a circulation pathway of the liquid helium to be provided and the superconducting coil to be cooled.

According to the embodiment described above, in at least one of the space on the inner peripheral side or the space on the outer peripheral side of the loop of the superconducting coil in the cryostat that stores the superconducting coil, a part of at least one of the top plate portion of the cryostat or the bottom plate portion of the cryostat is bent toward the inner side of the cryostat and joined to a part of the other of the top plate portion or the bottom plate portion.

Thus, even if the thickness of the housing member of the cryostat is made smaller than usual, for example, the strength of the cryostat can be secured, and reducing the thickness of the housing leads to reduction of the weight and the size of the cryostat. Furthermore, arranging the reinforcer in the space outside the bent cryostat can secure further strength.

Also, even in the case of increasing the size of the cryostat, adopting a concave structure for the structure of bending toward the inner side of the cryostat reduces deflection, as compared to the case of simply increasing the size of the housing, thus allowing the strength of the cryostat to be secured. That is, it is possible to maintain the strength of the housing while making it light.

The embodiment assumes an open magnetic resonance imaging apparatus; however, for example, a static magnetic field adjuster 50 may be applied to a magnetic resonance imaging apparatus in which the gradient magnetic field coil 103 and the transmitter coil 115 are stacked on the upper superconducting magnet 101-1 or the lower superconducting magnet 101-2 shown in the embodiment and the superconducting magnet only on one side is used. If an imaging space can be formed in the lower space in the case of the upper superconducting magnet 101-1 or can be formed in the upper space in the case of the lower superconducting magnet 101-2, imaging can be performed in the same manner as the imaging performed by an open magnetic resonance imaging apparatus.

The term “processor” used in the above description means, for example, circuitry such as a central processing unit (CPU), a graphics processing unit (GPU), an application-specific integrated circuit (ASIC), or a programmable logic device (e.g., a simple programmable logic device (SPLD), a complex programmable logic device (CPLD), or a field-programmable gate (FPGA)). If the processor is, for example, a CPU, the processor implements the functions by reading and executing programs stored in storage circuitry. On the other hand, if the processor is an ASIC, for example, its functions are directly incorporated into the circuitry of the processor as logic circuitry, instead of a program being stored in the storage circuitry. The processors described in connection with the above embodiments are not limited to single-circuit processors; a plurality of independent processors may be integrated into a single processor that implements the functions of the processors. Furthermore, the functions may be implemented by a single processor into which multiple components shown in the drawings are incorporated.

In addition, the functions described in the above embodiment may be implemented, for example, by installing a program for executing the processing in a computer, such as a workstation, and expanding the program in a memory. The programs that can cause the computer to execute the processing can be stored in a storage medium, such as a magnetic disk (a hard disk, etc.), an optical disk (CD-ROM, DVD, etc.), or a semiconductor memory and distributed through it.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A superconducting magnet comprising:
a loop-shaped superconducting coil for forming a static magnetic field; and
a cryostat having a top plate portion and a bottom plate portion and being a housing storing the superconducting coil,
wherein in at least one of a space on an inner peripheral side or a space on an outer peripheral side of the superconducting coil, a part of at least one of the top plate portion or the bottom plate portion is bent toward an inner side of the cryostat and joined to a part of the other of the top plate portion or the bottom plate portion.

2. The superconducting magnet according to claim 1, wherein a part of the bottom plate portion is bent toward the inner side of the cryostat and joined to a part of the top plate portion, and the superconducting magnet further comprises a reinforcer that is arranged in a space outside the cryostat in which the bottom plate portion is bent, the reinforcer being configured to support a load imposed on the cryostat.

3. The superconducting magnet according to claim 1, wherein a part of the top plate portion is bent toward the inner side of the cryostat and joined to a part of the bottom plate portion, and the superconducting magnet further comprises a fixer that is arranged in a space outside the cryostat in which the top plate portion is bent, the fixer being configured to fix a shim capable of adjusting the static magnetic field.

4. The superconducting magnet according to claim 1, wherein both a part of the top plate portion and a part of the bottom plate portion are bent toward the inner side of the cryostat and joined to each other, with a position of a joint portion between the part of the top plate portion and the part of the bottom plate portion adjusted to create a space having a size that allows a shim capable of adjusting the static magnetic field and a fixer configured to fix the shim to be arranged.

5. The superconducting magnet according to claim 1, wherein a thickness of the top plate portion is designed based on a size of the cryostat and an expected load on the top plate portion.

6. The superconducting magnet according to claim 1, wherein
the superconducting coil is formed of a plurality of coils having operating temperature zones differing from each other, and
the plurality of coils are arranged independently for each of the operating temperature zones, the plurality of coils being arranged in respective regions inside the cryostat that are separated from each other by the part of at least one of the top plate portion or the bottom plate portion bent toward the inner side of the cryostat and joined to the part of the other of the top plate portion or the bottom plate portion.

7. The superconducting magnet according to claim 1, further comprising a cold head for cooling the inner side of the cryostat using a refrigerator,
wherein in the space on the outer peripheral side of the superconducting coil, a part of at least one of the top plate portion or the bottom plate portion of the cryostat other than a position of the cold head is bent toward the inner side of the cryostat along a circumferential direction of the superconducting coil and joined to a part of the other of the top plate portion or the bottom plate portion.

8. The superconducting magnet according to claim 1, wherein a joint portion between the part of the top plate portion and the part of the bottom plate portion is formed by at least one of welding, adhesion, bolt tightening, press fitting, cooling fitting, shrink fitting, or rivet fastening.

9. A magnetic resonance imaging apparatus comprising:
a superconducting magnet for generating a static magnetic field;
a gradient magnetic field coil for generating a gradient magnetic field; and
an RF coil for irradiating a subject in an imaging space with an RF pulse,
wherein the superconducting magnet comprises:
a loop-shaped superconducting coil for forming the static magnetic field; and
a cryostat having a top plate portion and a bottom plate portion and being a housing storing the superconducting coil,
wherein in at least one of a space on an inner peripheral side or a space on an outer peripheral side of the superconducting coil, a part of at least one of the top plate portion or the bottom plate portion is bent toward an inner side of the cryostat and joined to a part of the other of the top plate portion or the bottom plate portion.
